(19) United States
(12) Patent Application Publication
(10) Pub. No.: US 2025/0370056 A1
(43) Pub. Date: Dec. 4, 2025

(54) PRE-AGING METHOD FOR PRE-AGING A BATTERY, AND TEST METHOD FOR TESTING SETS OF BATTERIES

(71) Applicant: AVL List GmbH, Graz (AT)

(72) Inventors: Mats IVARSON, Judendorf-Straßengel (AT); Helmut Peter GRASSBERGER, Graz (AT); Stefan SCHEIDEL, Graz (AT); Thomas TRAUSSNIG, Pfaffendorf (AT); Thomas EBNER, Hitzendorf (AT); Andreas FICSOR, Graz (AT); Simon ERKER, Graz (AT)

(73) Assignee: AVL List GmbH, Graz (AT)

(21) Appl. No.: 18/873,373

(22) PCT Filed: Jun. 7, 2023
(86) PCT No.: PCT/AT2023/060178

§ 371 Date: Dec. 10, 2024

(30) Foreign Application Priority Data
Jun. 10, 2022 (AT) A 50408/2022

(51) Int. Cl. G01R 31/392; G01R 31/367; G01R 31/387; G01R 31/396; H01M 10/42

(52) U.S. Cl. CPC G01R 31/392; G01R 31/367; G01R 31/387; G01R 31/396; H01M 10/4285

(57) ABSTRACT

The present invention relates to a pre-ageing method (10) and a pre-ageing system (20) for pre-ageing a battery (2) to a specified ageing condition, a test method (30) and a test system (40) for testing battery sets according to a specified test plan, as well as a computer program product.

The present invention relates to a pre-ageing method for pre-ageing a battery to a specified ageing condition, a test method for testing battery sets according to a specified test plan, a computer program product, a pre-ageing system for pre-ageing a battery to a specified ageing condition and a test system for testing battery sets according to a specified test plan.

The ageing behaviour of newly developed batteries is of great interest. The usual method for determining the ageing behaviour is to carry out ageing measurement tests using artificial load profiles. The load profiles are defined by a sequence of charging/discharging cycles, followed by pause times and a capacity and performance test and, if necessary, further tests. The parameters of the artificial profiles can be varied to obtain information about ageing behaviour under different conditions.

The state of the art involves carrying out the ageing measurement test on the basis of DOE (Design of Experiment) in order to obtain maximum information with the number of batteries used. A specific set of cycle parameters is applied to each individual battery and the cycle starts with a new condition up to a predefined ageing condition (also referred to as State of Health—SOH) of for example 75%.

In this method, the remaining capacity decreases over time depending on the selected parameters of the load profile. The resulting time required to reach the desired SOH depends to a great extent on the selected load profile. This can cause some batteries to reach the end of their service life very early, while other cells do not reach the desired SOH level. A battery only provides information about one parameter set of the load profile.

In addition to achieving different SOH values, the long duration of the known test method is disadvantageous. For example, to test batteries in an SOH range of 100% to 80% battery capacity, it is quite possible that these will have to go through 1,000 or more cycles. The associated long periods of time required are unavoidable if restricted to one set of cycle parameters, since—in the case of cycle parameters with a moderate influence on ageing—the ageing of the battery or the achievement of an SOH of 0 can take a long time.

It is the object of the present invention to remedy, at least in part, the disadvantages described above. In particular, it is the object of the present invention to provide, in a cost-effective and simple manner, methods and systems with which the testing of batteries is facilitated, in particular accelerated.

The above object is achieved by a pre-ageing method with the features of claim 1, a test method with the features of claim 9, a computer program product with the features of claim 13, a pre-ageing system with the features of claim 14 and a test system with the features of claim 15. Further features and details of the invention are disclosed in the dependent claims, the description and the drawings. Naturally, features and details described in connection with the pre-ageing method according to the invention also apply in connection with the test method according to the invention, the computer program product according to the invention, the pre-ageing system according to the invention as well as the test system according to the invention and vice versa, so that with regard to disclosure mutual reference is or can always be made to the individual aspects of the invention.

According to the invention, a pre-ageing method for pre-ageing at least one battery to a specified ageing condition is provided. The pre-ageing method according to the invention comprises the following steps:
specifying the ageing condition of the battery which is to be achieved,
selecting at least one ageing profile from a plurality of different ageing profiles, wherein each of the ageing profiles specifies at least one charging and/or discharging process with predefined ageing parameters for the battery,
applying the previously selected at least one ageing profile to the battery,
selecting at least one further ageing profile from the plurality of different ageing profiles, wherein the further ageing profile differs in at least one of the predefined ageing parameters from the previously selected ageing profile applied to the battery,
applying the previously selected at least one further ageing profile to the battery until the specified ageing condition of the battery has been reached.

Compared to the known ageing methods in which the same cycle is always applied to a battery, the pre-ageing method according to the invention enables an adapted battery ageing of the battery up to a desired ageing condition. This is particularly expedient when several batteries are aged in parallel. In this case, the pre-ageing method according to the invention has the advantage that, due to the different ageing profiles, several batteries can be aged relatively uniformly with respect to the period of time required.

The pre-ageing method according to the invention has a special application with regard to a test method according to the invention, preferably carried out subsequently, as will be explained in more detail later. For this purpose, batteries which have been pre-aged with the pre-ageing method according to the invention are advantageously used in order to make use of the advantages of fast and uniform battery ageing.

Nevertheless, it is possible already to use the pre-ageing method as such as a test method, wherein information about the battery ageing of the batteries can be obtained by applying the ageing profiles. In this respect, it can also be the case with the pre-ageing method that ageing information is obtained for the different ageing profiles.

The ageing condition can be described by the so-called SOH (State of Health). Advantageously, the ageing condition can be indicated solely by the SOH. The SOH is a measure of-along with other influencing variables—the capacity of the battery available in the respective ageing condition. In particular, it can be stated as an indication of the available residual capacity of the battery in relation to the original battery capacity or design capacity of the battery. Another SOH influencing variable relevant for operation is the (relative) change in internal resistance with advancing battery ageing (generally, an increase in internal resistance with ageing).

That the SOH adequately describes the ageing condition of the battery was established through appropriate experiments. For example, it was found that, with operation within certain operating parameters of the cell (including, but not limited to, charging/discharging current, cell voltage limits, temperature), the SOH is only to an insignificant extent dependent on the previous stress on the batteries. Instead, the ageing condition can be adequately described by the SOH and the history of battery ageing can be disregarded when operating within cell chemistry-dependent parameters. In this case, a single battery cell can for example be used as a battery. However, several interconnected battery cells or battery modules of a battery pack can also be used. And, of course, it is also possible to use a battery pack as a battery, so that the entire battery pack with all its battery cells is pre-aged. The battery pack can in particular be a traction battery for an electric drive of a motor vehicle. In the case of a cost-intensive traction battery, ageing over the long service life of the motor vehicle plays a particularly important role, which must be investigated by means of tests before a battery is used in a motor vehicle.

In the present case, an ageing profile is understood to be a specification of at least one charging and/or discharging process for the battery. Preferably, an ageing profile comprises the specification of several charging and/or discharging processes defined on the basis of predefined ageing parameters, in particular several charging and discharging cycles. Thus, an ageing profile can for example define 2 to 300, 4 to 200, 10 to 150 or the like charging and discharging cycles predefined on the basis of ageing parameters. In this way, an ageing profile in each case specifies charging/discharging cycles for the battery which are always applied to the battery under the same ageing parameters for a predetermined number of cycles. The ageing parameters are to be understood as parameters that can be set and varied during the charging/discharging cycles which have an influence on the ageing of the battery. These can in particular be external environmental parameters and/or electrical operating parameters of the battery.

In the pre-ageing method according to the invention, at least two different ageing profiles are provided which are selected and applied to the battery. To distinguish the ageing profiles, the at least one second ageing profile is referred to as the at least one further ageing profile. It differs in one or more ageing parameters from the other ageing profile, or all other ageing profiles. In order to decide when to switch between the ageing profiles, a further step of determining a intermediate ageing condition can be provided. The intermediate ageing condition can also be compared with the specified ageing condition. It is also possible to predefine the ageing parameters of the further ageing profile depending on a intermediate ageing condition, in particular a comparison of the intermediate ageing condition with the specified ageing condition.

The application of the at least one additional ageing profile continues until the predefined termination criterion of the pre-ageing method is met. The termination criterion is that the previously specified ageing condition is reached. As a result, a battery is obtained which has been quickly and uniformly pre-aged to the specified ageing condition and can now be used, in particular for the previously mentioned test method according to the invention.

It is not necessary, but possible, that all method steps of the method according to the invention are carried out in the order in which they are named. This means that individual method steps can also be carried out in a different order, or simultaneously. For example, the specifying of the ageing condition of the battery which is to be achieved can also take place after selecting the ageing profile, or the ageing condition which is to be achieved can also be adjusted during the course of the method, if necessary.

It is advantageous if further ageing profiles are selected from the plurality of different ageing profiles and applied to the battery until the specified ageing conditions of the battery are reached, whereby the further ageing profiles differ in at least one or more of the predefined ageing parameters at least from the previously selected ageing profile applied to the battery. Also, the other ageing profiles may differ from several or all of the previously selected and applied ageing profiles in at least one or more of the predefined ageing parameters. For example, the application of even more different ageing profiles achieves an even more uniform and faster pre-ageing of the battery. In addition, more information about the ageing behaviour can be obtained than with a fixed ageing profile.

It is also advantageous if at least one of the selected ageing profiles is configured for ageing the battery at a first rate and at least one other of the selected ageing profiles is configured for ageing the battery at a second rate different from the first rate. For example, it is typically assumed that very intensive loading will cause faster ageing than low loading. For example, the first rate may be a typically slow ageing rate with low charging and/or discharging current, while the second rate may be a rapid ageing rate with typically very high charging and/or discharging current. This ensures the already-mentioned uniformity, because not only are ageing parameters changed between the ageing profiles which ensure a similar and equally fast ageing, ageing profiles with different rates of ageing are actually applied to the battery.

Advantageously, the specified ageing parameters are at least two of a temperature, a mechanical pressure, a charging current, a discharging current, a state of charge, in particular a delta state of charge, and a pulse frequency. Most particularly, it can also be at least three or more or all of the above. The environment of the battery can be influenced by the temperature and the mechanical pressure, so that these ageing parameters can be regarded as external environmental parameters that can have an influence on the ageing of the battery. The remaining parameters are electrical operating parameters of the battery which can be set during charging and/or discharging. With the state of charge, for example, it can be specified as an ageing parameter how much the battery is charged and discharged between charging/discharging cycles. For example, the state of charge can be predefined in absolute or relative terms. Different pre-definitions are also possible with regard to the other ageing parameters, for example with regard to the discharging current and charging current, for which it is for example possible to pre-define the peak current and/or the average current.

It is advantageous if the specified ageing parameters in the ageing profiles lie within a specified parameter range. This parameter range may be limited, in particular with regard to the battery design. This prevents the battery from being operated outside of its design, for example at temperatures below −40° C. if it is only designed for a maximum of down to −40° C. This ensures that the pre-ageing does not cause any damage to the battery which may only become noticeable later and makes the pre-aged battery no longer usable, in particular testable, in the way that would be possible under regular real conditions.

In addition, it is preferable if the specified ageing condition is in the range of 95% to 70%, in particular 90% to 75% residual capacity, measured against a design capacity of the battery. For example, SOHs of 95%, 90%, 85%, 80%, 75%, and/or 70% can be considered.

It is particularly preferable if a plurality of batteries are pre-aged in parallel. Advantageously, the specified ageing condition is the same for all batteries. For this purpose, the batteries can for example be located in a battery arrangement with a parallel connection of the batteries and a voltage source for charging the batteries and an electrical consumer for discharging the batteries. The batteries can preferably be identical in design, but can also be different from each other, for example in terms of cell chemistry, structure, number of cells, etc. The batteries advantageously have the same battery capacity of 100% of the design capacity. By means of the pre-ageing method according to the invention, all batteries can be brought to substantially the same ageing condition after approximately the same period of time, because the different ageing profiles used enable the ageing of the batteries to be evened out.

The respective ageing profiles can preferably be selected differently for all of the batteries pre-aged in parallel. As already mentioned, this also allows the batteries to be tested, since different ageing profiles are used and thus more information about the battery ageing of the batteries, in particular of the same design, can be collected. Alternatively, the same ageing profiles can be selected and applied for the respective batteries in order to cause the most uniform ageing possible.

It is also advantageous that, in order to achieve the specified ageing condition of all batteries, the ageing profiles for the batteries are selected taking into account intermediate ageing conditions of the other batteries. As mentioned above, an intermediate ageing condition, in particular in relation to the specified ageing condition, can be determined or monitored. In the case of several batteries, however, this can be used not only as feedback for the selection of the ageing profile of the battery with the intermediate ageing condition, but can also be used for the other batteries. For example, it can be determined that one battery ages comparatively more rapidly than the others, because an intermediate ageing condition of this battery is higher than that of the other batteries. In this case, an ageing profile can be selected for the other batteries which causes faster ageing than in the battery with the already high intermediate ageing condition, in order to bring the batteries back into line with each other in terms of their intermediate ageing conditions. By comparing the intermediate ageing conditions in this way and feeding them back to the pre-ageing method for the selection of the respective ageing profiles, it is possible to keep the batteries within a specified battery capacity corridor that the batteries do not leave, collectively, within the framework of the pre-ageing method. This enables active control of the pre-ageing of several batteries on the basis of the ageing profiles.

While it is particularly advantageous to carry out the ageing of all batteries at the same rate on average, i.e. to achieve an average ageing rate, a further and decisive advantage is to be able to measure as many different combinations of ageing parameters as possible at each current ageing level (SOH). The information obtained in this way can be coupled with each other. For this purpose, a model can be formed from the data measured so far on the relationship between ageing parameters and ageing. The model can then be used to select new ageing parameter combinations where little information is as yet available, as well as to adhere to a specified ageing rate corridor in particular.

The subject matter of the present invention also includes a test method for testing battery sets according to a specified test plan. The test method comprises the following steps:
providing a first battery set with at least one first battery having a first battery capacity,
providing at least one second battery set with at least one second battery having a second battery capacity different from the first battery capacity,
specifying the test plan for testing the battery sets, wherein the test plan specifies charging and/or discharging processes with predefined test parameters for the battery sets, and
testing the two battery sets in parallel according to the specified test plan.

The test method according to the invention thus allows a considerable acceleration of a testing of batteries, in particular battery sets, according to a specified test plan. This is achieved in that batteries with different battery capacities are provided and tested. Thus, batteries can be tested within a certain range of an ageing condition, in particular an SOH range, for example from 100% to 80%, without really testing all batteries over the necessary number of cycles from 100% design capacity to 80% according to the test plan. The test plan can in particular be a DOE test plan.

The batteries of the individual battery sets can in particular be of identical design, i.e. in particular with the same cell chemistry, the same cell structure and/or the same design capacity. For example, a battery of a certain type can be tested using a comprehensive sample, so that a variability between the batteries is covered for the test method. Different test parameters can also be applied to the different batteries, so that different information can be obtained regarding battery ageing during the ageing of the individual batteries.

Each of the at least two battery sets therefore preferably includes several batteries, i.e. at least two, three or more batteries, for example two to ten or three to six batteries. This allows a larger sample for testing and thus more valid test results.

In particular, the battery capacity is understood to be the maximum capacity of a battery which, as explained above, can be specified in relation to its design capacity. Most particularly, the battery capacities of the at least one first battery and the at least one second battery are residual capacities, whereby the batteries originally had substantially the same output capacity or, in other words, were designed with substantially the same design capacity.

The internal battery resistance generally increases with progressive ageing, and depending on the cell chemistry. The change in internal resistance is associated with influences on, for example, the performance of the battery. In symbiosis with battery capacity determination, corresponding measurements provide a more complex picture for the description of the influences caused by battery ageing (performance, range).

In particular, the same parameters, most particularly electrical operating parameters, as have been explained in relation to the ageing parameters, can be used as test parameters.

Preferably, the two battery sets have each been pre-aged, using the pre-ageing method according to the invention, to their battery capacities, in particular residual capacities. This makes it easy to provide the battery sets with the batteries. In particular, several batteries of a battery pack may, if possible, have the same specified ageing condition in the form of the same battery capacity if they have been pre-aged for the test method according to the invention using the pre-ageing method according to the invention.

It is also possible to combine the test method according to the invention and the pre-ageing method according to the invention, whereby the pre-ageing method is carried out before the test method. The pre-ageing method can be carried out for at least one of the battery sets in the test method. Advantageously, the arrangements or interconnections of the battery sets used for the pre-ageing method can also be used for the test method.

Preferably, the test parameters for the batteries specified by the test plan are different. This allows the testing of in particular identical batteries at different SOHs with different test parameters to obtain different ageing information during the ageing of the batteries as a result of performing the test.

For example, this makes it possible to find out the extent to which battery ageing is affected by temperature, if, for example, one battery is tested at 20° C., another battery is tested at 0° C. and yet another battery is tested at −20° C. according to the test plan. The test parameter in which the batteries differ is therefore the ambient temperature. This means the test can be used to obtain different information regarding the ageing behaviour at different temperatures for this one particular battery type. In addition, this allows the advantageous provision of battery sets consisting of batteries with different battery capacities. If, for example, testing is to be carried out in an SOH range of 100% to 80% SOH, a first battery set with three first batteries at 100% SOH and a second battery pack with three second batteries at 90% SOH will for example be provided. These are tested according to the test plan, so that one battery from each battery set is tested at 20° C., one at 0° C. and one at −20° C. In this way, the testing duration of the test method can be roughly halved compared to a test method in which a battery set with three batteries would have to be completely aged from 100% SOH to 80% SOH. Nevertheless, the same amount of ageing information is obtained over the entire SOH range from 100% to 80%.

The subject matter of the present invention also includes a computer program product comprising commands which, when the program is run on a computer, cause this to carry out the pre-ageing method according to the invention and/or the test method according to the invention.

Thus, a computer program product according to the invention brings the same advantages as have been explained in detail with reference to the pre-ageing method according to the invention and the test method according to the invention.

The computer program product can be a computer program per se or a product, for example a computer-readable data storage device, on which a computer program can be stored to carry out the pre-ageing method according to the inventions and/or the test method according to the invention.

In addition, the object mentioned in the introduction is achieved by a pre-ageing system for pre-ageing at least one battery to a specified ageing condition. The pre-ageing system comprises the following modules:
at least one specification module for specifying the ageing condition of the battery which is to be achieved,
at least one selection module for selecting at least one ageing profile from a plurality of different ageing profiles, wherein each of the ageing profiles specifies a charging and/or discharging process with predefined ageing parameters for the battery, and for selecting a further ageing profile from the plurality of different ageing profiles, wherein the further ageing profile differs in at least one of the predefined ageing parameters from the previously selected ageing profile applied to the battery,
at least one application module for applying the previously selected at least one ageing profile to the battery and for applying the previously selected further ageing profile to the battery, and
at least one determination module for determining whether the specified ageing condition of the battery has been reached.

Thus, a pre-ageing system according to the invention brings the same advantages as have been explained in detail with reference to the pre-ageing method according to the invention.

In particular, the pre-ageing system can be configured to carry out the pre-ageing method according to the invention.

Individual or all modules of the pre-ageing system can for example in each case be implemented by a separate computer program code or jointly by a common computer program code and/or by separate or common functional units of a computer or electronic components. It is also possible that individual modules are implemented in a common module. The pre-ageing system may in particular comprise one or more computers or be formed by one or more computers which may include the individual modules.

Finally, the object mentioned in the introduction is also achieved by a test system for testing battery sets. The test system comprises the following modules:
at least one provision module for providing a first battery set with at least one first battery having a first battery capacity and for providing at least one second battery set with at least one second battery having a second battery capacity different from the first battery capacity,
at least one specification module for specifying the test plan for testing the battery sets, wherein the test plan specifies charging and/or discharging processes with predefined test parameters for the battery sets, and
at least one test module for parallel testing of the two battery sets according to the specified test plan.

Parallel testing can for example be carried out separately or together. This means that at least one test module can be used for separate or parallel testing of the two battery sets. Thus, a test system according to the invention brings the same advantages as have been explained in detail with reference to the test method according to the invention.

In particular, the test system can be configured to carry out the test method according to the invention.

The test system and the pre-ageing system can also be combined into a common system, whereby individual modules, for example the specification module, can only be provided once and can be used for the test system and the pre-ageing system.

Individual or all modules of the test system can for example in each case be implemented by a separate computer program code or jointly by a common computer program code and/or by separate or common functional units of a computer or electronic components. It is also possible that individual modules are implemented in a common module. The test system may in particular comprise one or more computers or be formed by one or more computers which may include the individual modules.

Further advantages, features and details of the invention are explained in the following description, in which exemplary embodiments are described in detail with reference to the drawings. In each case schematically:

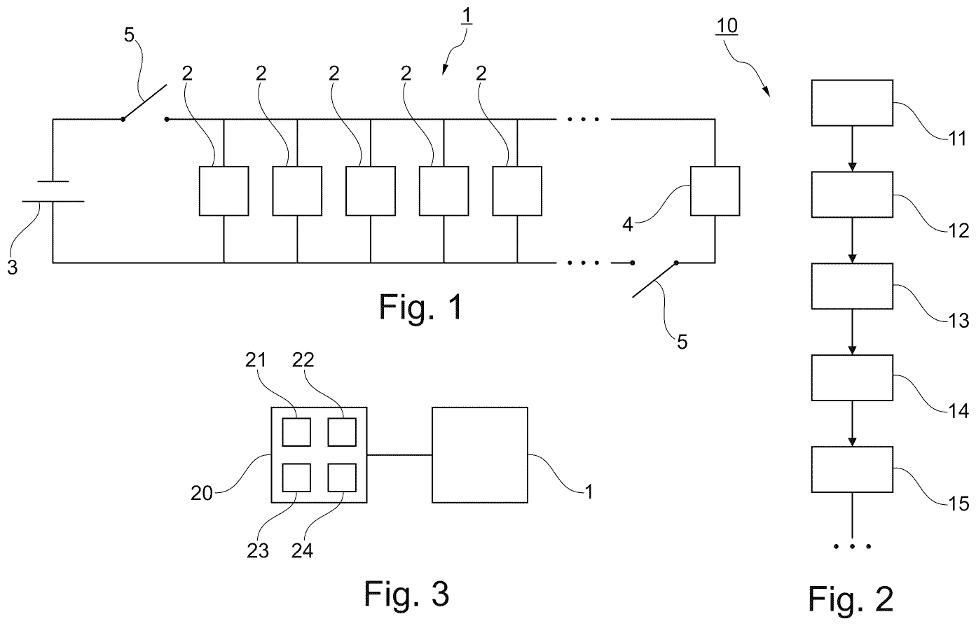

FIG. 1 shows a schematic representation of a battery circuit,

FIG. 2 shows a schematic representation of a pre-ageing method according to an exemplary embodiment of the invention,

FIG. 3 shows a schematic representation of a pre-ageing system according to an exemplary embodiment of the invention,

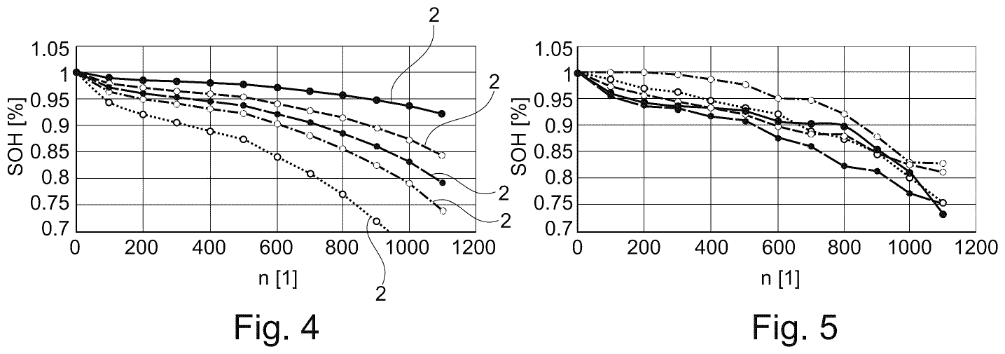

FIG. 4 shows a schematic representation of the ageing of batteries by means of an ageing process according to the prior art,

FIG. 5 shows a schematic representation of the ageing of batteries using the pre-ageing method of FIG. 2 or the pre-ageing system of FIG. 3,

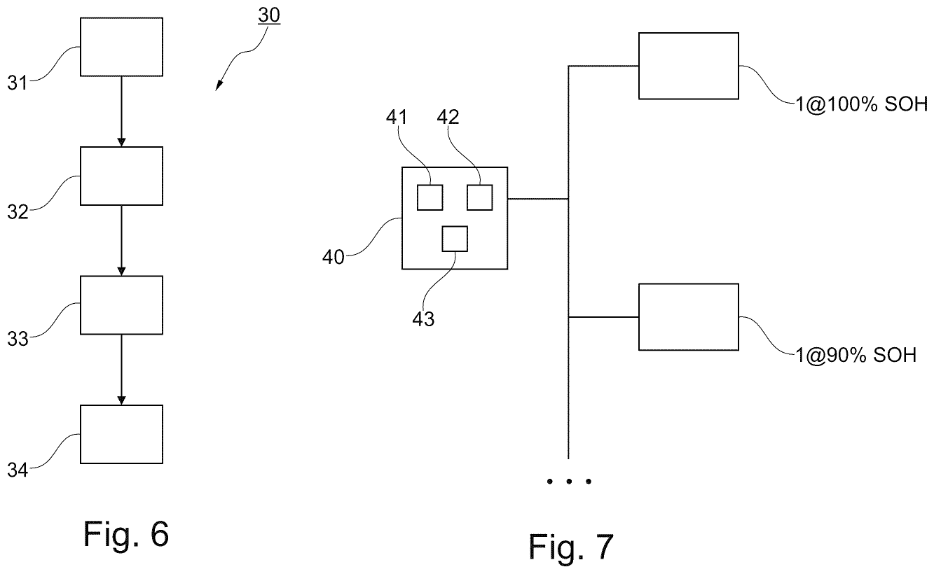

FIG. 6 shows a schematic representation of a test method according to an exemplary embodiment of the invention,

FIG. 7 shows a schematic representation of a test system according to an exemplary embodiment of the invention,

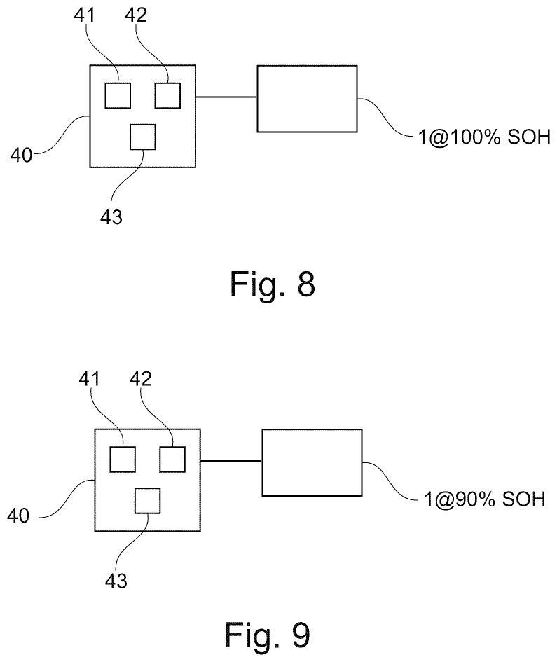

FIG. 8 shows a schematic representation of an alternative to the test system of FIG. 7;

FIG. 9 shows a schematic representation of an alternative to the test system of FIG. 7, in particular in combination with FIG. 8;

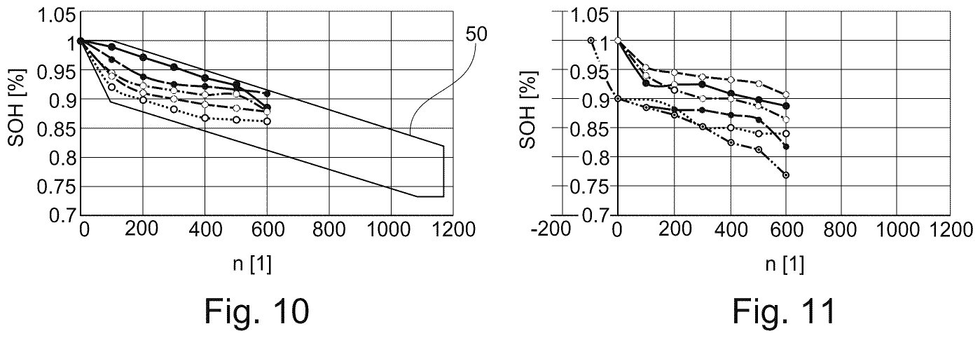

FIG. 10 shows a further schematic representation of the ageing of batteries using the pre-ageing method of FIG. 2 or the pre-ageing system of FIG. 3, and

FIG. 11 shows a schematic representation of the ageing of batteries during the test method of FIG. 6 or in the test system of FIG. 7.

Identical or functionally identical elements are each designated with the same reference sign in FIGS. 1 to 11.

FIG. 1 shows schematically a battery circuit 1 with several batteries 2 which are connected in parallel to a voltage source 3 to charge the batteries 2 and to a consumer 4 to discharge the batteries 2. The voltage source 3 and the consumer 4 can in each case be connected by means of switches 5 in the battery circuit 1. The batteries 2 can be identical in design. The batteries 2 can for example be battery cells, battery modules or battery packs.

As indicated in FIG. 1 by an ellipsis, even more than the five batteries 2 shown by way of example can be connected in parallel. Alternatively, it is also possible that fewer than five batteries 2, for example only two or only one battery 2 is provided in the battery circuit 1. Furthermore, it can also be the case that each of the batteries 2 is assigned its own voltage source 3, its own consumer 4 and/or its own switch 5, so that FIG. 1 shows only a simple variant of a possible battery circuit 1 which allows the pre-ageing method 10 explained with reference to FIG. 2.

The pre-ageing method 10 is used to pre-age the one or more batteries 2 (to which reference is made in the following) of the battery circuit 1 to a specified ageing condition. In a specification step 11 of the pre-ageing method 10, the ageing condition of the batteries 2 which is to be achieved is specified.

In a first selection step 12, an ageing profile is then selected from a plurality of different ageing profiles. Each of the ageing profiles specifies a particular number of charging/discharging cycles with predefined ageing parameters for the batteries 2 which are carried out by means of the voltage source 3 and the consumer 4. The ageing parameters can for example be environmental parameters such as temperature or mechanical pressure on the batteries 2 and electrical operating parameters such as charging and discharging current. In a first application step 13, the ageing profile selected in the first selection step 12 is applied to the batteries 2.

The first selection step 12 and the first application step 13 are now substantially repeated in a second selection step 14 and a second application step 15, whereby further repetitions are also possible, as indicated in FIG. 2 by an ellipsis, until the specified ageing condition of the batteries 2 is reached. In contrast to the first selection step 12, in the second selection step 14 and possibly further, i.e. third, fourth, etc. selection steps (not shown here), an ageing profile different from the previously applied ageing profile is selected. The ageing profile differs in one or more of the predefined ageing parameters, so that the batteries 2 are loaded differently with the different ageing profiles.

FIG. 3 shows a pre-ageing system 20 such as can be used to carry out the pre-ageing method 10 of FIG. 2. The pre-ageing system 20 has a specification module 21 for carrying out the specification step 11, a selection module 22 for carrying out the selection steps 12, 14, an application module 23 for carrying out for the application steps 13, 15 and a determination module 24 which determines whether the specified ageing condition of the battery 2 has been reached and thus allows the termination of the pre-ageing method 10.

FIG. 4 now shows the ageing of five batteries 2 in a diagram of SOH (State of Health) as an indication of the residual capacity of the batteries 2 compared to their design capacity (normalised to 100%) over the number n of charging/discharging cycles according to the prior art. In an ageing method according to the prior art, a specific charging/discharging cycle is applied to each of the batteries 2 which remains the same throughout. On the one hand, this means that individual batteries 2 take a very long time to reach a certain ageing condition, for example of SOH=80% (the top three batteries 2 in FIG. 4 need over n=1,000 cycles). And on the other hand, this leads to the visible uneven ageing. Accordingly, it is not possible to age the batteries 2 evenly with the prior art method.

If the method shown in FIG. 4 is used as a test method in which ageing information about the batteries 2 is obtained, this is unsatisfactory because, after 1,000 cycles for all batteries 2, a conclusion regarding their ageing behaviour as a function of the specific charging/discharging cycles cannot be drawn over the same SOH range of, for example, 100% to 75%.

The case is different with the pre-ageing method 10 according to the invention, the result of which can be seen in the diagram in FIG. 5. Here, batteries 2 were pre-aged according to the pre-ageing method 10 with the pre-ageing system 20 and reached an SOH of about 80% more rapidly (after approx. n=1,000 cycles) and are also aged much more uniformly, so that their SOH is comparable.

If the pre-ageing method 10 as was used in FIG. 5 is used as a test method to obtain ageing information, it was possible to test all five batteries 2 over an SOH range of 100% to approx. 80% with different ageing profiles, so that a greater wealth of information on ageing is available here. However, it is even more preferable to use the pre-ageing method 10 before the actual test method 30, as shown in FIG. 6.

FIG. 6 shows schematically a test method 30 for testing battery sets, such as the battery set of FIG. 1 comprising the five batteries 2 shown there as well as a further battery set, not shown, which in turn again comprises a plurality of batteries 2. FIG. 7 shows a corresponding test system 40 by means of which the test method 30 can be carried out.

In a first provision step 31, a first battery set with first batteries 2 with a first battery capacity, in particular residual capacity, a first battery set with first batteries 2 with a first battery capacity, in particular residual capacity, for example connected in a battery circuit 1 like the one shown in FIG. 1, is provided by means of a provision module 41. In a second provision step 32, a second battery set with second batteries 2 with a second battery capacity which is different from the first battery capacity is provided by the same provision module 41 of the test system 40.

For example, as can be seen in FIG. 7 and FIG. 11, the first battery set may comprise three batteries 2 with battery capacities of 100% SOH, and the second battery set may also comprise three batteries 2 with battery capacities of 90% SOH which have in particular been pre-aged rapidly and uniformly with few cycles using the pre-ageing method 10 according to the invention.

In FIG. 7 it is indicated that further provision steps (not shown) are possible in order to provide further battery sets with further batteries 2 in which the batteries 2 have other SOHs, for example 95% SOH and 85% SOH, as a result of which the test method 30 can be accelerated even further, as will become clear from the following.

A specification step 33 is then carried out by a specification module 42 of the test system 40 in order to specify the test plan for testing the battery sets. The test plan specifies charging/discharging cycles with predefined test parameters for the battery sets, whereby these are different for the tested batteries 2.

A test step 34 is then carried out by a test module 43 in which the battery sets are tested in parallel according to the specified test plan. The result can be seen in FIG. 11, which shows that batteries 2 are fully tested in the SOH range of 100 to approx. 80% in only 600 cycles, instead of over 1,000 cycles and only in a partially matching SOH range of 100% to just under 95% of all batteries 2, as would be the case with an ageing test according to FIG. 4.

Contrary to what is shown in FIG. 7, the provision of the battery sets 1 with different capacities (e.g. 95%, 90%, etc.) can also take place in parallel. Accordingly, the test method 30 can be carried out on the different battery sets 1 having different capacities. Accordingly, different test systems 40 can also be used, on which the battery sets 1 of different capacities are tested in parallel or consecutively, as shown in FIGS. 8 and 9 by way of example, whereby the data from both test systems 40 of FIGS. 8 and 9 can then be merged.

FIG. 10 shows a battery capacity corridor 50 as preferably adhered to by a specified parameter range for the ageing parameters of the ageing profiles. Alternatively or additionally, the battery capacity corridor 50 can be adhered to through a determination and feedback of intermediate ageing conditions of the batteries 2. The feedback can take place in the selection step 14 and further selection steps in order to select the further ageing profile of the batteries 2 in such a way that all the batteries 2 remain within the battery capacity corridor 50 and preferably reach the specified ageing condition at the same time.

The above explanations of the embodiments describe the present invention exclusively in the context of examples.

### LIST OF REFERENCE SIGNS

1 battery circuit
2 battery
3 voltage source
4 consumer
5 switch
10 pre-ageing method
11 specification step
12 first selection step
13 first application step
14 second selection step
15 second application step
20 pre-ageing system
21 specification module
22 selection module
23 application module
24 determination module
30 test method
31 first provision step
32 second provision step
33 further specification step
34 test step
40 test system
41 provision module
42 specification module
43 test module
50 battery capacity corridor

1. A pre-ageing method for pre-ageing at least one battery to a specified ageing condition, comprising:
specifying the ageing condition of the battery which is to be achieved,
selecting at least one ageing profile from a plurality of different ageing profiles, wherein each of the ageing profiles specifies at least one charging and/or discharging process with predefined ageing parameters for the battery,
applying the previously selected at least one ageing profile to the battery,
selecting at least one further ageing profile from the plurality of different ageing profiles, wherein the further ageing profile differs in at least one of the predefined ageing parameters from the previously selected ageing profile applied to the battery,
applying the previously selected at least one further ageing profile to the battery until the specified ageing condition of the battery has been reached.

2. The pre-ageing method according to claim 1, wherein until the specified ageing condition of the battery is reached, further ageing profiles are selected from the plurality of different ageing profiles and applied to the battery, wherein the further ageing profiles differ in at least one of the predefined ageing parameters at least from the previously selected ageing profile applied to the battery.

3. The pre-ageing method according to claim 1, wherein at least one of the selected ageing profiles is configured for ageing the battery at a first rate and at least one other of the selected ageing profiles is configured for ageing the battery at a second rate different from the first rate.

4. The pre-ageing method according to claim 1, wherein the specified ageing parameters are at least two of a temperature, a mechanical pressure, a charging current, a discharging current, a state of charge and a pulse frequency.

5. The pre-ageing method according to claim 1, wherein the specified ageing parameters in the ageing profiles lie within a specified parameter range.

6. The pre-ageing method according to claim 1, wherein the specified ageing condition is in the range of 95% to 70% residual capacity, measured against a design capacity of the battery.

7. The pre-ageing method according to claim 1, wherein a plurality of batteries are pre-aged in parallel, wherein the specified ageing condition is the same for all batteries.

8. The pre-ageing method according to claim 7, wherein order to achieve the specified ageing condition of all batteries, the ageing profiles for the batteries are selected taking into account intermediate ageing conditions of the other batteries.

9. A test method for testing battery sets according to a specified test plan, comprising:
providing a first battery set with at least one first battery having a first battery capacity,
providing at least one second battery set with at least one second battery having a second battery capacity different from the first battery capacity,
specifying the test plan for testing the battery sets, wherein the test plan specifies charging and/or discharging processes with predefined test parameters for the battery sets, and
testing the two battery sets in parallel according to the specified test plan.

10. The test method according to claim 9, wherein the two battery sets have each been pre-aged to their battery capacities using the a pre-ageing method.

11. The test method according to claim 9, wherein each of the battery sets comprises several batteries.

12. The test method according to claim 9, wherein the test parameters for the batteries specified by the test plan are different.

13. A computer program product comprising commands which, when the program is run on a computer, cause this to carry out the pre-ageing method according to claim 1.

14. A pre-ageing system for pre-ageing at least one battery to a specified ageing condition, wherein the pre-ageing system having:
at least one specification module for specifying the ageing condition of the battery which is to be achieved,
at least one selection module for selecting at least one ageing profile from a plurality of different ageing profiles, wherein each of the ageing profiles specifies a charging and/or discharging process with predefined ageing parameters for the battery, and for selecting a further ageing profile from the plurality of different ageing profiles, wherein the further ageing profile differs in at least one of the predefined ageing parameters from the previously selected ageing profile applied to the battery.
at least one application module for applying the previously selected at least one ageing profile to the battery and for applying the previously selected further ageing profile to the battery, and
at least one determination module for determining whether the specified ageing condition of the battery has been reached.

15. A test system for testing battery sets, comprising:
at least one provision module for providing a first battery set with at least one first battery having a first battery capacity and for providing at least one second battery set with at least one second battery having a second battery capacity different from the first battery capacity,
at least one specification module for specifying the test plan for testing the battery sets, wherein the test plan specifies charging and/or discharging processes with predefined test parameters for the battery sets, and
at least one test module for parallel testing of the two battery sets according to the specified test plan.

16. A computer program product comprising commands which, when the program is run on a computer, cause this to carry out the test method according to claim 9.
